(19) United States
(12) Patent Application Publication
(10) Pub. No.: US 2021/0292644 A1
(43) Pub. Date: Sep. 23, 2021

(54) LIGHT LUMINESCENT PARTICLE

(71) Applicant: MERCK PATENT GMBH, Darmstadt (DE)

(72) Inventor: Arjan MEIJER, Reinheim (DE)

(73) Assignee: Merck Patent GmbH, Darmstadt (DE)

(21) Appl. No.: 16/332,412

(22) PCT Filed: Sep. 7, 2017
(86) PCT No.: PCT/EP2017/072426

§ 371 Date: Mar. 12, 2019

(30) Foreign Application Priority Data
Sep. 13, 2016 (EP) 16188530.6

(51) Int. Cl. C09K 11/02

(52) U.S. Cl. CPC C09K 11/025; B82Y 20/00

(57) ABSTRACT

The present invention relates to a light luminescent particle, use of the light luminescent particle and method for preparation of the light luminescent particle. The present invention further relates to composition, an optical medium, and an optical device and method for preparation of thereof.

### FIELD OF THE INVENTION

The present invention relates to a light luminescent particle, use of the light luminescent particle and method for preparation of the light luminescent particle. The present invention further relates to composition, an optical medium, and an optical device and method for preparation of thereof.

### BACKGROUND ART

Light luminescent particles comprising at least one nanosized fluorescent material are known in the prior art.

For example, as described in US 2011/0240931 A1, US 2014/0264196 A1, WO 2014/196319 A1, and US 2011/0068322 A1.

### Patent Literature

1. US 2011/0240931 A1

2. US 2014/0264196 A1

3. WO 2014/196319 A1

4. US 2011/0068322 A1

### Non Patent Literature

None

### SUMMARY OF THE INVENTION

However, the inventors newly have found that there is still one or more of considerable problems for which improvement is desired, as listed below.
1. A novel light luminescent particle comprising at least one nanosized fluorescent material and a matrix material which can prevent Quantum Yield drop of the nanosized fluorescent material in a fabrication process of the light luminescent particle, preferably it leads better Quantum Yield of the light luminescent particle than the Quantum Yield of a nanosized fluorescent material itself, is required.
2. A novel light luminescent particle comprising at least one nanosized fluorescent material, which can prevent any damage of the nanosized fluorescent material caused by irradiation of Vacuum Ultra Violet light, is desired.
3. A novel light luminescent particle comprising at least one nanosized fluorescent material, which can have better barrier properties about oxygen and/or moisture, is still a need for improvement.
4. A novel light luminescent particle enables a simple fabrication process for fabrication of a luminescent particle comprising at least one nanosized fluorescent material, is desired

The inventors aimed to solve one or more of the above mentioned problems 1 to 4.

Surprisingly, the inventors have found that a novel light luminescent particle (100) comprising a porous medium (110) comprising a pore (111), and at least one nanosized fluorescent material (120) in the pore (111), wherein the light luminescent particle (100) comprises a barrier layer (130) placed over the porous medium (110), solves one or more of the problems 1 to 4. Preferably said light luminescent particle (100) of the present invention solves all the problems 1 to 4 at the same time.

In another aspect, the present invention relates to use of the light luminescent particle (100) in an optical medium (200) or a composition.

In another aspect, the present invention further relates to composition comprising the light luminescent particle (100), and one or more members of the group consisting of solvents, transparent matrix materials, and another type of light luminescent materials which is different from the light luminescent particle (100).

In another aspect, the present invention also relates to an optical medium (200) comprising the light luminescent particle (100).

In another aspect, the present invention further relates to an optical device (300) comprising the optical medium (200).

In another aspect, the present invention also relates to method for preparing of the light luminescent particle (100), wherein the method comprises following step (a) and (b) in this sequence,

(a) mixing a nanosized fluorescent material (120) and a porous medium (110)

(b) mixing the porous medium (110) containing the nanosized fluorescent material (120) obtained in step (a) and a precursor of the barrier layer.

In another aspect, the present invention further relates to method for preparing of the composition, wherein the method contains following step (x),

(x) mixing the light luminescent particle (100), and one or more members of the group consisting of solvents, transparent matrix materials, and another type of light luminescent materials which is different from the light luminescent particle (100).

In another aspect, the present invention further relates to method for preparing of the optical medium wherein the method comprises following step (y),
(y) providing the composition onto a substrate.

In another aspect, the present invention further relates to method for preparing of the of the optical device (300), wherein the method comprises following step (z),
(z) providing the optical medium (200) in an optical device.

### DESCRIPTION OF DRAWINGS

FIG. 1 shows a cross sectional view of a schematic of one embodiment of a light luminescent particle (100).

FIG. 2 shows a cross sectional view of a schematic of one embodiment of an optical medium (200).

FIG. 3 shows a cross sectional view of a schematic of one embodiment of an optical device (300).

FIG. 4 shows a cross sectional view of a schematic of another embodiment of an optical device (300).

FIG. 5 shows a cross sectional view of a schematic of another embodiment of an optical device (300).

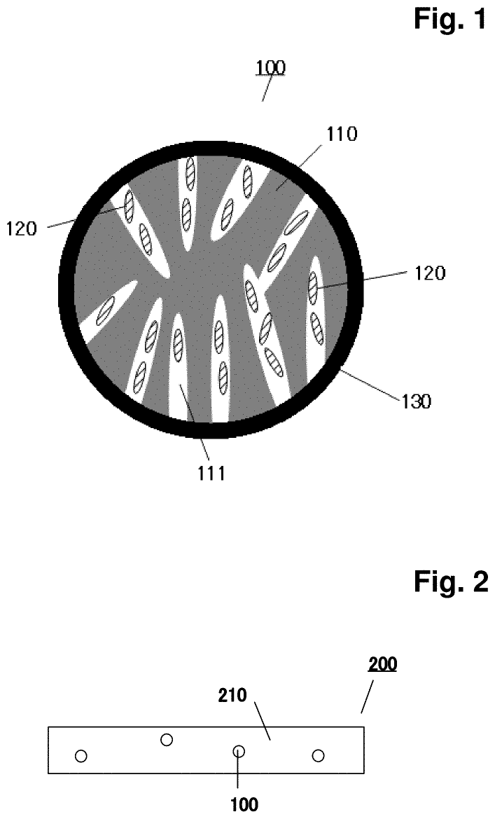

### LIST OF THE REFERENCE SIGNS IN FIG. 1

100. a light luminescent particle

110. a porous medium

111. a pore

120. a nanosized fluorescent material

130. a barrier layer

### LIST OF THE REFERENCE SIGNS IN FIG. 2

200. an optical medium (light conversion sheet)

100. a light luminescent particle

210. a matrix material

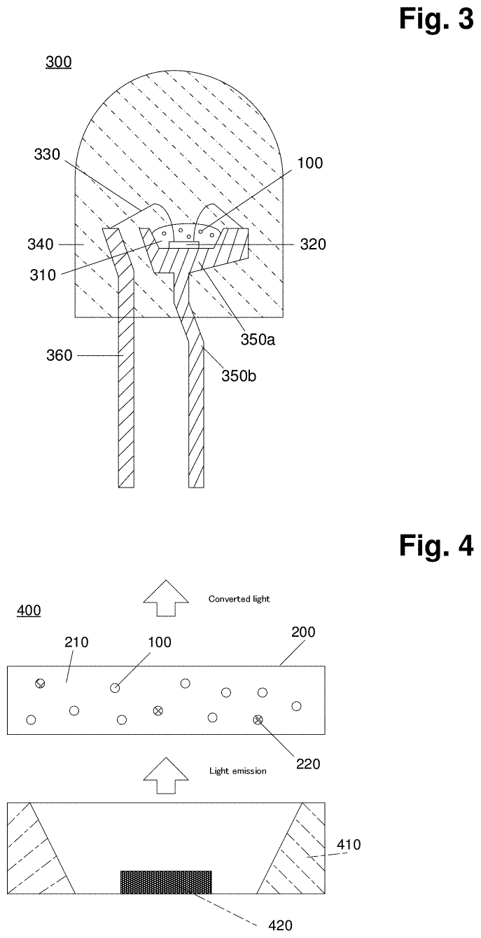

### LIST OF THE REFERENCE SIGNS IN FIG. 3

300. an optical device (a light emitting diode device)

100. a light luminescent particle

310. a matrix material

320. a light emitting diode element

330. a conductive wire

340. a molding material

350 a. a cup

350 b. a mount lead

360. an inner lead

### LIST OF THE REFERENCE SIGNS IN FIG. 4

400. a light emitting diode device

100. a light luminescent particle

200. an optical medium (a color conversion sheet)

210. a matrix material

220. an another type of inorganic fluorescent material (optional)

410. a casing

420. a light emitting diode element

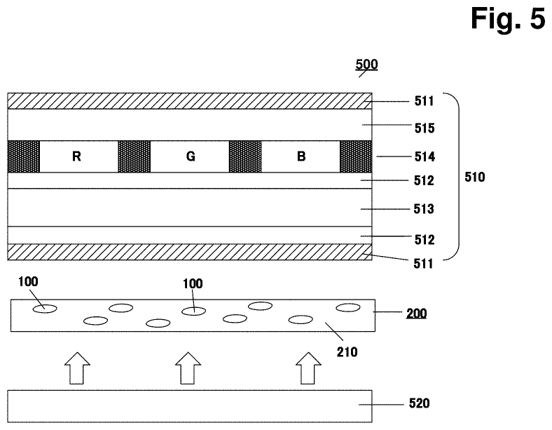

### LIST OF THE REFERENCE SIGNS IN FIG. 5

500. a liquid crystal display device

100. a light luminescent particle

200. an optical medium (a color conversion sheet)

210. a matrix material

511. a polarizer

512. an electrode

513. a liquid crystal layer

514. a color filter

515. a substrate

520. a backlight unit

### DETAILED DESCRIPTION OF THE INVENTION

According to the present invention, the light luminescent particle (100) comprising a porous medium (110) comprising a pore (111), and at least one nanosized fluorescent material (120) in the pore (111), wherein the light luminescent particle (100) comprises a barrier layer (130) placed over the porous medium (110), solves one or more of the problems 1 to 4. Preferably said light luminescent particle (100) solves all the problems 1 to 4 at the same time.

Barrier layer (130)

According to the present invention, any type of publically available transparent barrier layer materials can be used.

In a preferred embodiment of the present invention, the barrier layer (130) is a layer obtained from one or more members of the group consisting of a perhydropolysilazane, alkoxides represented by following formula (I), and a polysiloxane,

M_{z}(OR)_{zx} (I)

wherein the formula (I), M is Si, Al, Va or Ti; R is an alkyl chain having 1 to 25 carbon atoms with more preferably being of an alkyl chain having 1 to 15 carbon atoms; 1≤z; x is an oxidation number of M.

Thus in some embodiment of the present invention, the barrier layer (130) is the one selected from one or more members of the group consisting of a perhydropolysilazane, a polysiloxane, an aluminum oxide hydroxide, vanadium oxide hydroxide, titanium oxide hydroxide, and a silicon oxide hydroxide.

In a preferred embodiment of the present invention, the barrier layer (130) is the one selected from one or more members of the group consisting of a perhydropolysilazane, a polysiloxane, an aluminum oxide hydroxide, and a silicon oxide hydroxide.

According to the present invention, in some embodiments, the barrier layer (130) can be a single layer, double layers, or multilayers.

In case of the barrier layer (130) is double layers or multilayers, each layer of double layers or multilayers can be at each occurrence, identically or differently, one or more members of the group consisting of a perhydropolysilazane, a polysiloxane, an aluminum oxide hydroxide, and a silicon oxide hydroxide.

More preferably, the barrier layer (130) is a perhydropolysilazane, an aluminum oxide hydroxide, or silicon oxide hydroxide.

In some embodiments of the present invention, the barrier layer (130) covers at least a part of the surface of the porous medium (110). Preferably, the barrier layer (130) covers all surface of the porous medium (110) like described in FIG. 1.

Porous medium (110)

According to the present invention, any type of porous medium comprising a pore can be used to deposit nanosized fluorescent materials.

In a preferred embodiment of the present invention, the porous medium (110) is a porous particle selected from the group consisting of organic porous particle, inorganic porous particle.

According to the present invention, the shape of the porous medium (110) can be round, plate-shaped, elongated or irregularly shaped.

In a preferred embodiment of the present invention, the porous medium (110) is round or irregularly shaped.

In some embodiment of the present invention, the average diameter of the porous medium (110) is in the range from 10 nm to 100 μm with preferably being from 100 nm to 50 μm. Even more preferably, it is from 500nm-20 μm.

In a preferred embodiment of the present invention, the porous medium (110) comprises a plurality of nanosized fluorescent materials (120).

More preferably, the porous medium (110) comprises a plurality of pores (111) and a plurality of nanosized fluorescent materials in the pores(111).

In some embodiments of the present invention, the pore (111) of the porous medium (110) is a mesopore or a micropore.

In a preferred embodiment of the present invention, the porous medium (110) comprises a plurality of mesopores or micropores.

According to the present invention, the term “mesopore” means a pore having a pore size in the range from 2 nm to 100 nm.

According to the present invention, the term “micropore” stands for a pore having a pore size 2 nm or less.

For example, mesostructured aluminosilicate nanoparticles, aluminum doped silica mesoporous nanoparticles, mesostructured aluminum oxide nanoparticles, carbon mesoporous nanoparticles, silica mesoporous nanoparticles, titanium doped silica mesoporous nanoparticles available from Sigma-Aldrich, porous silicates available from Mo-Sci Co., Parteck SLC 500, Silica 5000, Kieselgel 300, Kieselgel 5000 from Merck Millipore can be used preferably.

In some embodiments, a known silica sol-gel or a metal sol-gel material can be used in a fabrication process of the light luminescent particle (100) to make an amorphous and porous silica/metal oxide (hydroxide) particles like described in Alexander Liberman et. al, Synthesis and surface functionalization of silica nanoparticles for nanomedicine, Surf Sci Rep. 2014 September-October; 69(2-3), 132-158.

Nanosized fluorescent material

According to the present invention, as the nanosized fluorescent material (120), any type of nanosized fluorescent material can be used preferably as desired.

A type of shape of the nanosized fluorescent material (120) of the present invention is not particularly limited.

For examples, spherical shaped, elongated shaped, star shaped, polyhedron shaped, pyramidal shaped, tetrapod shaped, banana shaped, platelet shaped, cone shaped, and irregular shaped semiconductor nanocrystals, can be used in this way.

In a preferred embodiment of the present invention, the nanosized fluorescent material (120) is a nanosized inorganic phosphor material, or a quantum sized material such as quantum dot, or quantum rod.

Without wishing to be bound by theory, it is believed that the nanosized fluorescent material can be used in a higher concentration ratio due to size effect and also may realize sharp vivid color(s) of a color conversion medium such as a color conversion film.

More preferably, the nanosized fluorescent material is a quantum sized material, with furthermore preferably being of a quantum dot material, quantum rod material.

According to the present invention, the term “nanosized” means the size in between 1 nm and 999 nm.

Thus, according to the present invention, the nanosized fluorescent material is taken to mean that the fluorescent material which size of the overall diameter is in the range from 1 nm to 999 nm. And in case of the material has elongated shape, the length of the overall structures of the fluorescent material is in the range from 1 nm to 999 nm.

According to the present invention, the term “quantum sized” means the size of the inorganic semiconductor material itself without ligands or another surface modification, which can show the quantum size effect.

Generally, quantum sized material such as quantum dot material, and/or quantum rod material can emit sharp vivid colored light due to quantum size effect.

In a preferred embodiment of the present invention, the quantum sized material is selected from the group consisting of II-VI, III-V, or IV-VI semiconductors and combinations of any of these.

More preferably, the quantum sized material is selected from the groups consisting of Cds, CdSe, CdTe, ZnS, ZnSe, ZnTe, ZnO, GaAs, GaP, GaAs, GaSb, HgS, HgSe, HgSe, HgTe, InAs, InP, InPZn, InPZnS, InSb, AlAs, AIP, AlSb, Cu₂S, Cu₂Se, CuInS2, CuInSe₂, Cu₂(ZnSn)S₄, Cu₂(InGa)S₄, TiO₂ alloys and combination of any of these, can be used preferably.

For example, for red emission use CdSe/CdS, CdSeS/CdZnS, CdSeS/CdS/ZnS, ZnSe/CdS, CdSe/ZnS, InP/ZnS, InP/ZnSe, InP/ZnSe/ZnS, InPZn/ZnS, InPZn/ZnSe/ZnS dots or rods, ZnSe/CdS, ZnSe/ZnS or combination of any of these, can be used preferably.

For example, for green emission use CdSe/CdS, CdSeS/CdZnS, CdSeS/CdS/ZnS, ZnSe/CdS, CdSe/ZnS, InP/ZnS, InP/ZnSe, InP/ZnSe/ZnS, InPZn/ZnS, InPZn/ZnSe/ZnS, ZnSe/CdS, ZnSe/ZnS or combination of any of these can be used preferably.

And for blue emission use, such as ZnSe, ZnS, ZnSe/ZnS, or combination of any of these, can be used.

As a quantum dot, publically available quantum dot, for examples, CdSeS/ZnS alloyed quantum dots product number 753793, 753777, 753785, 753807, 753750, 753742, 753769, 753866, InP/ZnS quantum dots product number 776769, 776750, 776793, 776777, 776785, PbS core-type quantum dots product number 747017, 747025, 747076, 747084, or CdSe/ZnS alloyed quantum dots product number 754226, 748021, 694592, 694657, 694649, 694630, 694622 from Sigma-Aldrich, can be used preferably as desired.

In some embodiments, the semiconductor nanocrystal can be selected from an anisotropic shaped structure, for example quantum rod material to realize better out-coupling effect (for example ACS Nano, 2016, 10 (6), pp 5769-5781).

Examples of quantum rod material have been described in, for example, the international patent application laid-open No. WO2010/095140A.

In a preferred embodiment of the invention, the length of the overall structures of the quantum sized material, such as a quantum rod material/or the quantum dot material, is from 1 nm to 100 nm, preferably, from 1 nm to 60 nm, even more preferably, from 1 nm to 30 nm, most preferably, it is from 1 nm to 10 nm.

Preferably, the nanosized fluorescent material such as quantum rod and / or quantum dot comprises a surface ligand.

The surface of the quantum rod and / or quantum dot materials can be over coated with one or more kinds of surface ligands.

Without wishing to be bound by theory it is believed that such a surface ligands may lead to disperse the nanosized fluorescent material in a solvent more easily.

In some embodiments of the present invention, the light luminescent particle (100) can further embraces a ligand onto the outermost surface of the barrier layer (130) to have better dispersivity in a solvent and/or a matrix material.

In another aspect, the present invention also relates to use of the light luminescent particle (100) in an optical medium or a composition.

In another aspect, the present invention also relates to a composition comprising the light luminescent particle (100).

In some embodiments of the present invention, the composition can further embrace one or more members of the group consisting of solvents, transparent matrix materials, and another type of light luminescent particles which is different from the light luminescent particle (100).

Solvent

In some embodiments of the present invention, the composition comprises solvent, if necessary.

Type of solvent is not particularly limited.

In some embodiments of the present invention, the solvent can be selected from the group consisting of purified water; ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate;; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, and glycerin; esters, such as, ethyl 3-ethoxypropionate, methyl 3-methoxypropionate and ethyl lactate; and cyclic asters, such as, γ-butyrolactone; chlorinated hydrocarbons, such as chloroform, dichloromethane, chlorobenzene, dichlorobenzene.

Those solvents are used singly or in combination of two or more, and the amount thereof depends on the coating method and the thickness of the coating.

Transparent matrix material

According to the present invention, a wide variety of publically known transparent materials suitable for optical devices can be used in this way.

According to the present invention, the term “transparent” means at least around 60% of incident light transmit at the thickness used in an optical medium and at a wavelength or a range of wavelength used during operation of an optical medium. Preferably, it is over 70%, more preferably, over 75%, the most preferably, it is over 80%.

In a preferred embodiment of the present invention, the transparent matrix material is a transparent polymer, a polysiloxane or a polysilazane.

According to the present invention the term “polymer” means a material having a repeating unit and having the weight average molecular weight (Mw) 1000 or more.

In a preferred embodiment of the present invention, the weight average molecular weight (Mw) of the transparent polymer (130) is in the range from 1,000 to 250,000 with being more preferably in the range from 20,000 to 150,000.

For examples, poly(sulfone amine), poly(ester amine), poly(amide amines), poly(urea urethane), poly(amine ester), poly(ester amides), polyester, polyethylenimine, polyvinyl alcohols, polyacrylonitrile, polyvinylidene chloride, ethylene vinylalcohol like disclosed in the polymer handbook 4^{th} edition (J. Brandrup, et al.,) can be used preferably.

Another type of light luminescent material

In some embodiments of the present invention, the composition can comprises one or more of another type of light luminescent materials which is different from the light luminescent particle (100).

In a preferred embodiment of the present invention, the light luminescent material is one or more members of the group consisting of an activator, inorganic fluorescent compound, and organic fluorescent compound.

Preferably, the activator is selected from the group consisting of Sc³⁺, Y³⁺, La³⁺, Ce³⁺, Pr³⁺, Nd³⁺, Pm³⁺, Sm³⁺, Eu³⁺, Gd³⁺, Tb³⁺, Dy³⁺, Ho³⁺, Er³⁺, Tm³⁺, Yb³⁺, Lu³⁺, Bi³⁺, Pb²⁺, Mn²⁺, Yb²⁺, Sm²⁺, Eu²⁺, Dy²⁺, Ho²⁺ and a combination of any of these.

More preferably, the activator is selected from the group consisting of Ce³⁺, Sm³⁺, Eu³⁺, Tb³⁺, Bi³⁺, Eu²⁺ and a combination of any of these.

In a preferred embodiment of the invention, the inorganic fluorescent material is selected from the group consisting of sulfides, thiogallates, nitrides, oxynitrides, silicates, aluminates, apatites, borates, oxides, phosphates, halophosphates, sulfates, tungstenates, tantalates, vanadates, molybdates, niobates, titanates, germinates, halides based phosphors, and a combination of any of these.

Suitable inorganic fluorescent materials described above are well known to the skilled person and mentioned e.g. in the phosphor handbook, 2^{nd} edition (CRC Press, 2006), pp. 155-pp. 338 (W. M. Yen, S. Shionoya and H. Yamamoto), WO2011/147517A, and WO2012/034625A.

More preferably, the inorganic fluorescent compound is selected from the group consisting of YVO₄:Yb³⁺, YVO₄:Eu³⁺, YVO₄:Eu³⁺, Bi³⁺, YVO₄:Ce³⁺, Tb³⁺, Y₂O₃:Bi³⁺, Eu³⁺, or Y₂O₃:Ce³⁺, Tb³⁺ based phosphors, and a combination of any of these.

In a preferred embodiment of the present invention, the said inorganic fluorescent compound has a medium size in the range from 1 nm to 100 nm. More particularly preferably, the medium size is in the range from 3 nm to 50 nm. The most preferably, from 5 nm to 25 nm.

In another preferred embodiment, an organic fluorescent material is present and preferably selected from the group consisting of Fluoresceins, Rhodamines, Coumarins, Pyrenes, Cyanines, Perylenes, Di-cyano-methylenes, metal complexes and a combination of any of these.

Suitable organic fluorescent materials described above are well known to the skilled person and mentioned e.g. in the phosphor handbook, 2^{nd} edition (CRC Press, 2006), pp. 769-pp. 774 (W. M. Yen, S. Shionoya and H. Yamamoto).

The organic fluorescent material can be selected from commercially available Coumarin 6 (from Sigma-ALDRICH), DY-707, 730, 732 or 750 (from Funakoshi Ltd.), NK-3590 (from Hayashibara Ltd.), LDS698, 720, 750 or 765 (from Exciton).

Preferably, the internal quantum efficiency of the fluorescent compound and/or the inorganic fluorescent semiconductor quantum material is more than 80%; more preferably, it is 90% or more.

The internal quantum efficiency of the fluorescent compounds of the present invention can be measured with an absolute PL (photoluminescence) quantum yield measurement system, such as C9920-02G (Hamamatsu).

Optical medium

In another aspect, the present invention further relates to an optical medium (200) comprising the light luminescent particle (100).

In some embodiments of the present invention, the optical medium (100) can be an optical sheet, for example, a color filter, color conversion film, remote phosphor tape, or another film or filter.

According to the present invention, the term “sheet” includes film and / or layer like structured mediums.

Optical device

In another aspect, the invention further relates to an optical device (300) comprising the optical medium (200).

In some embodiments of the present invention, the optical device (300) can be a liquid crystal display device (LCD), Organic Light Emitting Diode (OLED), backlight unit for an optical display, Light Emitting Diode device (LED), Micro Electro Mechanical Systems (here in after “MEMS”), electro wetting display, or an electrophoretic display, a lighting device, and / or a solar cell.

In another aspect, the present invention also relates to method for preparing of the light luminescent particle (100), wherein the method comprises following step (a) and (b) in this sequence,
(a) mixing a nanosized fluorescent material (120) and a porous medium (110),
(b) mixing the porous medium (110) containing the nanosized fluorescent material (120) obtained in step (a) and a precursor of the barrier layer.

Preferably, the mixing step (a) and (b) are carried out at room temperature under inert condition such as under N₂ condition.

In a preferred embodiment of the present invention, in step (a) and/or step (b), solvent is used. Preferably, said solvent is selected from the group consisting of purified water; ethylene glycol monoalkyl ethers, such as, ethylene glycol monomethyl ether, ethylene glycol monoethyl ether, ethylene glycol monopropyl ether, and ethylene glycol monobutyl ether; diethylene glycol dialkyl ethers, such as, diethylene glycol dimethyl ether, diethylene glycol diethyl ether, diethylene glycol dipropyl ether, and diethylene glycol dibutyl ether; ethylene glycol alkyl ether acetates, such as, methyl cellosolve acetate and ethyl cellosolve acetate; propylene glycol alkyl ether acetates, such as, propylene glycol monomethyl ether acetate (PGMEA), propylene glycol monoethyl ether acetate, and propylene glycol monopropyl ether acetate; aromatic hydrocarbons, such as, benzene, toluene and xylene; ketones, such as, methyl ethyl ketone, acetone, methyl amyl ketone, methyl isobutyl ketone, and cyclohexanone; alcohols, such as, ethanol, propanol, butanol, hexanol, cyclo hexanol, ethylene glycol, and glycerin; esters, such as, ethyl 3-ethoxypropionate, methyl 3-methoxypropionate and ethyl lactate; and cyclic asters, such as, γ-butyro-lactone; chlorinated hydrocarbons, such as chloroform, dichloromethane, chlorobenzene, dichlorobenzene.

Those solvents can be used singly or in combination of two or more, and the amount thereof depends on the coating method and the thickness of the coating.

More preferably, propylene glycol alkyl ether acetates, such as, propylene glycol monomethyl ether acetate (hereafter “PGMEA”), propylene glycol monoethyl ether acetate, propylene glycol monopropyl ether acetate, purified water or alcohols is used.

Even more preferably, purified water is used.

In step (b), as a precursor of the barrier layer, one or more members of the group consisting of a perhydropolysilazane, alkoxides represented by following formula (I), and a polysiloxane can be used preferabl,

M_{z}(OR)_{zx} (I)

wherein the formula (I), M is Si, Al, Va or Ti; R is an alkyl chain having 1 to 25 carbon atoms with more preferably being of an alkyl chain having 1 to 15 carbon atoms; 1≤z; x is an oxidation number of M.

For example of alkoxides, tetraethyl orthosilicate (TEOS), methyl triethoxysilane (MTEOS), sodium silicate, lithium silicate, kalium silicate, aluminum isopropoxide, Tripropyl orthoaluminate Al (OC3H7)₃ (TPOAI), Titanium alkoxide, vanadium alkoxide or a combination of any of these can be used preferably.

For examples of polysiloxanes for the barrier layer (130), polysiloxanes like disclosed in WO 2013/151166 A1, U.S. Pat. No. 8,871,425 B2 can be used preferably.

For examples of polysilazane for the barrier layer (130) according to the present invention, polysilazanes like disclosed in WO 201 4/1 9631 9 Al, US 2011/0240931 A1 can be used preferably.

In another aspect, the present invention further relates to method for preparing of the composition, wherein the method contains following step (x),

(x) mixing the light luminescent particle (100), and one or more members of the group consisting of solvents, transparent matrix materials, and another type of light luminescent materials which is different from the light luminescent particle (100).

According to the present invention, one or more of the solvents, the transparent matrix materials, and another type of light luminescent materials described in the section of “Solvents”, “Transparent matrix materials”, “Another type of light luminescent materials” can be used preferably as desired.

In another aspect, the present invention further relates to method for preparing of the optical medium wherein the method comprises following step (y),

(y) providing the composition onto a substrate.

In another aspect, the present invention further relates to method for preparing of the optical device (300), wherein the method comprises following step (z),

(z) providing the optical medium (200) in an optical device.

### EFFECT OF THE INVENTION

The present invention provides;
1. a novel light luminescent particle comprising at least one nanosized fluorescent material and a matrix material which can prevent Quantum

Yield drop of the nanosized fluorescent material in a fabrication process of the light luminescent particle, preferably it leads better Quantum Yield of the light luminescent particle than the Quantum Yield of a nanosized fluorescent material itself,
2. a novel light luminescent particle comprising at least one nanosized fluorescent material, which can prevent any damage of the nanosized fluorescent material caused by irradiation of Vacuum Ultra Violet light,
3. a novel light luminescent particle comprising at least one nanosized fluorescent material, which can have better barrier properties about oxygen and / or moisture,
4. a novel light luminescent particle enables a simple fabrication process for fabrication of a luminescent particle comprising at least one nanosized fluorescent material.

Definition of Terms

The term “semiconductor” means a material which has electrical conductivity to a degree between that of a conductor (such as copper) and that of an insulator (such as glass) at room temperature.

The term “inorganic ” means any material not containing carbon atoms or any compound that containing carbon atoms ionically bound to other atoms such as carbon monoxide, carbon dioxide, carbonates, cyanides, cyanates, carbides, and thiocyanates.

The term “emission” means the emission of electromagnetic waves by electron transitions in atoms and molecules.

The working examples 1-8 below provide descriptions of the present invention, as well as an in detail description of their fabrication.

### WORKING EXAMPLES

### Comparative Example 1

### Fabrication of a Light Luminescent Particle Without a Porous Medium

0.10 g of quantum rods (hereafter “Q-rods”) in 2-propanol solution (3 wt. %) (from Merck KGaA) was used.

First, 2-propanol of the quantum rods solution was removed with the rotavap and then 49.00 g of pyridine was added to dilute the mixture of q-rods and pyridine. Then 13.10 mL of PHPS NN110-20 in xylene (from Merck KGaA-AZ) was added to the obtained mixture.

Then the mixture was heated up to 75° C. under argon and stirred for 24 h at 75° C. under argon.

Finally, sample was taken.

### Comparative Example 2

### Fabrication of a Light Luminescent Particle Without a Barrier Layer

1 g (or mL) of quantum rods (hereafter “Q-rods”) in 2-propanol solution (3 wt. %) (from Merck KGaA) was used.

First, 2-propanol of the quantum rods solution was removed with the rotavap and then 14.7 g (or mL) of pyridine was added to dilute the mixture of q-rods and pyridine.

Silica 5000 (nonpolar, from Merck Millipore) was added to the Qrod/pyridine solution (Qrods: Silica/1:2), and mixed at the rotavap for 1 hour. Then a sample was taken.

### Working Example 1

### Fabrication of a Light Luminescent Particle (100)

1 g of quantum rods (hereafter “Q-rods”) in 2-propanol solution (3 wt. %) (From Merck KGaA) was used.

First, 2-propanol of the quantum rods solution was removed with the rotavap and then 14.7 g of pyridine was added to dilute the mixture of q-rods and pyridine.

Then, Silica 5000 (nonpolar, from Merck Millipore) was added to the Qrod/pyridine solution (Qrods: Silica/1:2) and mixed at the rotavap for 1 hour. Afterwards additional pyridine was added to dilute the mixture for the batch size.

Then, PHPS NN110-20 (in xylene) was added to the obtained mixture and heated up to 75° C. argon and stirred for 24 h at 75° C. under argon. A sample was taken.

### Working Example 2

### Measurements of Absolute Quantum Yield (QY) Value of the Samples.

The absolute Quantum Yield (QY) values, absorption (hereafter Abs.), center wavelength (CWL) and full width at half maximum (hereafter FWHM) of the samples obtained in comparative example 1, 2 and working example 1 were measured directly by using an absolute photoluminescence QY spectrometer (Hamamatsu model: Quantaurus C11347)

Table 1 shows the measurement results of the samples.

TABLE 1

| | QY | Abs. | CWL | FWHM |
|---|---|---|---|---|
| Examples | [%] | [%] | [nm] | [nm] |
| The luminescent particle obtained | 37.1 | 30.2 | 629.5 | 32.4 |
| in Comparative example 1 | | | | |
| The luminescent particle obtained | 54.8 | 24.3 | 630.7 | 32.2 |
| in Comparative example 2 | | | | |
| The luminescent particle obtained | 83.3 | 23.7 | 630.0 | 31.9 |
| in Working example 1 | | | | |

The luminescent particle obtained in working example 1 shows better Quantum Yield.

### Working Example 3

### Fabrication of a Light Luminescent Particle (100)

The light luminescent particle was fabricated in the same manner as described in working example 1 except for Kieselgel 300 (from Merck Millipore) was used instead of Silica 5000 and barrier layer was fabricated via sol gel process with TEOS instead of PHPS NN110-20.

In this example, 22.18 mL TEOS was diluted with 66.4 mL ethanol and slowly added to the mixture, afterwards the mixture was stirred for 2 additional hours at Room Temperature (hereafter RT).

### Working Example 4

### Fabrication of a Light Luminescent Particle (100)

The light luminescent particle was fabricated in the same manner as described in working example 3 except for Parteck SLC 500 (from Merck Millipore) was used instead of Kieselgel.

### Working Example 5

### Fabrication of a Light Luminescent Particle (100)

The light luminescent particle was fabricated in the same manner as described in working example 1 except for TEOS was used instead of PHPS NN110-20.

In this example, 22.18 mL TEOS was diluted with 66.4 mL ethanol and it was slowly added to the mixture, afterwards the obtained mixture was stirred for 2 additional hours at RT.

Then finally, three samples No. 1, No. 2, and No. 3 were taken.

### Working Example 6

### Measurements of Absolute Quantum Yield (QY) Value of the Films

The absolute Quantum Yield (QY) values, absorption (hereafter Abs.), center wavelength (CWL) and full width at half maximum (hereafter FWHM) of the samples obtained in working example 5 and comparative example 2 were measured directly by using an absolute photoluminescence QY spectrometer (Hamamatsu model: Quantaurus C11347).

Table 2 shows the measurement results of the samples.

TABLE 2

| | QY | Abs | CWL | FWHM |
|---|---|---|---|---|
| Sample | [%] | [%] | [nm] | [nm] |
| Light luminescent particles | 53.0 | 25.6 | 633.7 | 31.0 |
| obtained in comparative | | | | |
| example 2 | | | | |
| Sample No. 1 obtained in | 71.8 | 24.6 | 631.2 | 33.5 |
| working example 5 | | | | |
| Sample No. 2 obtained in | 66.2 | 26.3 | 631.2 | 33.5 |
| working example 5 | | | | |
| Sample No. 3 obtained in | 68.1 | 24.9 | 632.0 | 33.5 |
| working example 5 | | | | |

Sample No. 1 to No. 3 show better quantum yield.

### Working Example 7

### Fabrication of Optical Medium (200)

The light luminescent particle (100) obtained in working example 1 was dispersed in a PVA-water mixture (PVA : purified water=1 : 10), then the mixture was dispensed on a glass substrate.

Then it was cured on a hotplate at 80° C. for 30 min.

Finally, the optical film 1 was obtained.

### Comparative Example 3

### Fabrication of Optical Medium

The film 2 was fabricated in the same manner as described in working example 4, expect for the light luminescent particle obtained in comparative example 2 was used.

### Working Example 8

### Measurements of Absolute Quantum Yield (QY) Value of the Films

The absolute Quantum Yield (QY) values, absorption (hereafter Abs.), center wavelength (CWL) and full width at half maximum (hereafter FWHM) of the films obtained in working example 7 and comparative example 3 were measured directly by using an absolute photoluminescence QY spectrometer (Hamamatsu model: Quantaurus C11347)

Table 3 shows the measurement results of the films.

TABLE 3

| | QY | Abs. | CWL | FWHM |
|---|---|---|---|---|
| Sample | [%] | [%] | [nm] | [nm] |
| Film 2 obtained in | 53.3 | 34.1 | 629.97 | 32.37 |
| comparative example 3 | | | | |
| Film 1 obtained in working | 67.3 | 37.3 | 629.23 | 32.29 |
| example 6 | | | | |

As mentioned in the table 3, film 1 obtained in working example 4 shows better Quantum Yield.

1. A light luminescent particle (100) comprising a porous medium (110) comprising a pore (111), and at least one nanosized fluorescent material (120) in the pore (111), wherein the light luminescent particle (100) comprises a barrier layer (130) placed over the porous medium (110).

2. The light luminescent particle (100) according to claim 1, wherein the barrier layer (130) is a layer obtained from one or more members of the group consisting of a perhydropolysilazane, alkoxides represented by following formula (I), and a polysiloxane,
M_{z}(OR)_{zx} (I)
wherein the formula (I), M is Si, Al, Va or Ti; R is an alkyl chain having 1 to 25 carbon atoms; 1≤z; x is an oxidation number of M.

3. The light luminescent particle (100) according to claim 1, wherein the barrier layer (130) is the one selected from one or more members of the group consisting of a perhydropolysilazane, a polysiloxane, an aluminum oxide hydroxide, vanadium oxide hydroxide, titanium oxide hydroxide, and a silicon oxide hydroxide.

4. The light luminescent particle (100) according to claim 1, wherein the barrier layer (130) is the one selected from a perhydropolysilazane, an aluminum oxide hydroxide, or a silicon oxide hydroxide.

5. The light luminescent particle (100) according to claim 1, wherein the pore (111) of the porous medium (110) is a mesopore or a micropore.

6. The light luminescent particle (100) according to claim 1, wherein the porous medium (110) contains a plurality of pores (111) and a plurality of nanosized fluorescent materials (120) in the pores (111).

7. The light luminescent particle (100) according to claim 1, wherein the porous medium (110) is selected from the group consisting of organic porous medium, inorganic porous medium, or a combination of any of these.

8. (canceled)

9. Composition comprising the light luminescent particle (100) according to claim 1, and a solvent.

10. An optical medium (200) comprising the light luminescent particle (100) according to claim 1.

11. An optical device (300) comprising the optical medium (200) according to claim 10.

12. Method for preparing of the light luminescent particle (100) according to claim 1, wherein the method comprises following step (a) and (b) in this sequence,
(a) mixing a nanosized fluorescent material (120) and a porous medium (110),
(b) mixing the porous medium (110) containing the nanosized fluorescent material (120) obtained in step (a) and a precursor of the barrier layer.

13. Method for preparing of the composition according to claim 9, wherein the method contains following step (x),
(x) mixing the light luminescent particle (100), and one or more members of the group consisting of solvents, transparent matrix materials, and another type of light luminescent materials which is different from the light luminescent particle (100).

14. Method for preparing of the optical medium (200) according to claim 10, wherein the method comprises following step (y),
(y) providing the composition onto a substrate.

15. Method for preparing of the optical device (300) according to claim 11, wherein the method comprises following step (z),
(z) providing the optical medium (200) in an optical device.
